(19) United States
(12) Patent Application Publication
(10) Pub. No.: US 2011/0198706 A1
(43) Pub. Date: Aug. 18, 2011

(54) SEMICONDUCTOR CELL STRUCTURE, SEMICONDUCTOR DEVICE INCLUDING SEMICONDUCTOR CELL STRUCTURE, AND SEMICONDUCTOR MODULE INCLUDING SEMICONDUCTOR DEVICE

(76) Inventors: Kun-Ho KWAK, Hwaseong-si (KR); Hyung-Moo PARK, Seoul (KR)

(21) Appl. No.: 12/948,904

(22) Filed: Nov. 18, 2010

(30) Foreign Application Priority Data
Feb. 12, 2010 (KR) 10-2010-0013480

(51) Int. Cl. H01L 27/088

(52) U.S. Cl. 257/401; 257/E27.06

(57) ABSTRACT

The semiconductor cell structure includes unit cells that do not protrude from one another along columns and rows. The unit cells include active regions and gate patterns. The semiconductor cell structure also includes dummy patterns and conductive patterns. The gate patterns intersect the active regions. The dummy patterns electrically connect the unit cells. Dummy patterns are disposed at least between gate patterns in the selected unit cell. The conductive patterns are electrically connected to the dummy patterns. The semiconductor cell structure is disposed in a semiconductor device and a semiconductor module.

### CROSS-REFERENCE TO RELATED APPLICATION

This application claims priority under 35 U.S.C. §119 to Korean Patent Application No. 10-2010-0013480 filed on Feb. 12, 2010, the entire disclosure of which is hereby incorporated by reference.

### BACKGROUND

1. Field

Example embodiments of the inventive concepts relate to a semiconductor cell structure, a semiconductor device including the semiconductor cell structure, and a semiconductor module including the semiconductor device.

2. Description of Related Art

A semiconductor device, for example, a static random access memory (SRAM), is being fabricated to highly integrate semiconductor cell structures to comply with reduction in the design rule. Each of the semiconductor cell structures may include unit cells. Each of the unit cells may include transistors, which may be disposed to make the best use of an area of a unit cell selected to correspond to the reduction in the design rule.

In this case, in each of the semiconductor cell structures, the unit cells may be arranged in a zigzag to maximize or increase circuital performance of the transistors. The selected unit cell may planarly protrude from adjacent unit cells. Thus, a distance between components of the transistors in the selected unit cell may be increased more than before the design rule is reduced. The components of the transistors in the selected unit cell may become farther away from components of transistors in the adjacent unit cells than before the design rule is reduced.

The components of the unit cells may not sufficiently have pattern fidelity, which may be ensured by mask patterns of a semiconductor photomask, due to the zigzag arrangement of the unit cells. Conductive patterns disposed commonly on the semiconductor cell structures may be formed in a zigzag due to the zigzag arrangement of the unit cells. The conductive patterns may have an electrical resistance more than before the design rule is reduced. In addition, the semiconductor device, which may include unit cells arranged in a zigzag in the semiconductor structures, may be disposed in a semiconductor module and a processor-based system. Electrical properties of the semiconductor module and the processor-based system may be degraded because of the zigzag-arranged unit cells of the semiconductor structures.

### SUMMARY

The present invention provides a semiconductor cell structure, a semiconductor device and a semiconductor module including unit cells having a predetermined or given alignment relationship, which may improve electrical properties.

Example embodiments of the inventive concepts provide a semiconductor cell structure, a semiconductor device, and a semiconductor module in which unit cells are aligned not to protrude from one another along columns and rows so as to form substantially elongated conductive patterns on the unit cells.

In accordance with an example embodiment of the inventive concepts, a semiconductor cell structure includes at least one unit cell, each unit cell including first through fourth active regions sequentially disposed in the at least one unit cell, the first through fourth active regions parallel to one another, first and second gate patterns disposed perpendicular to the first, third, and fourth active regions, the second gate pattern being aligned with the first gate pattern, wherein the first gate pattern is disposed on the first active region, and the second gate pattern is disposed on the third and fourth active regions, and third and fourth gate patterns disposed perpendicular to the first, second, and fourth active regions, the fourth gate pattern being aligned with the third gate pattern, wherein the third and fourth gate patterns are parallel to and facing the first and second gate patterns, the third gate pattern is disposed on the first and second active regions, and the fourth gate pattern is disposed on the fourth active region, first dummy patterns disposed on opposite edges of the at least one unit cell, the first dummy patterns being parallel to one another and configured to electrically connect to the first and fourth gate patterns, respectively; and a conductive pattern electrically connected to the first dummy patterns to form a straight line interposed between the first through fourth gate patterns.

In an example embodiment, the first dummy patterns are aligned with the first through fourth gate patterns in a vertical direction along a cross-section of the semiconductor cell structure and contact the first and fourth gate patterns, respectively. In another example embodiment, the first dummy patterns are disposed above the first through fourth gate patterns in a vertical direction along a cross-section of the semiconductor cell structure, contact the first and fourth gate patterns, respectively, and partially cover at least one of the first and third gate patterns and at least one of the second and fourth gate patterns.

In another example embodiment, the first dummy patterns are disposed between the first through fourth gate patterns in a vertical direction along a cross-section of the semiconductor cell structure, protrude from top surfaces of the first and fourth gate patterns and extend at least partially over the top surfaces of the first and fourth gate patterns, respectively.

In an example embodiment, the semiconductor cell structure further includes a second dummy patter. The at least one unit cell includes first, second and third unit cells, the second and third unit cells configured to electrically connect to the first unit cell, the second unit cell disposed in one of a lower end portion and an upper end portion of the first unit cell and equal in phase to the first unit cell, the second dummy pattern electrically connected to at least one of the first and fourth gate patterns of the second unit cell and configured to contact the first dummy pattern electrically connected to at least one of the first and fourth gate patterns of the first unit cell at a first cell boundary line between the first and second unit cells, and the third unit cell disposed on at least one of a left end portion and a right end portion of the first unit cell, the third unit cell including first through fourth active regions, wherein at least one of first, third, and fourth active regions and first, second, and fourth active regions of the third unit cell are configured to electrically connect to at least one of first, third, and fourth active regions and first, second, and fourth active regions of the first unit cell at a second cell boundary line between the first and third unit cells.

In another example embodiment of the inventive concepts, a semiconductor device includes at least one unit cell in a semiconductor substrate, each unit cell including first and second active regions configured to contact, first end portions of each unit cell, the first and second active regions sequentially disposed parallel to each other, third and fourth active regions sequentially disposed parallel to each other between the first and second active regions, the third and fourth active regions configured to extend from the first end portions of each unit cell toward each other, first and second gate patterns on the first and second active regions, respectively, the first and second gate patterns disposed perpendicular to the first and second active regions and configured to diagonally face each other, a third gate pattern disposed perpendicular to the second and fourth active regions, the third gate pattern being aligned with the first gate pattern, and a fourth gate pattern disposed perpendicular to the first and third active regions, the fourth gate pattern being aligned with the second gate pattern, first and second dummy patterns configured to contact the first and second gate patterns, respectively, extend from the first and second gate patterns, and contact second end portions disposed perpendicular to the first end portions, the first and second dummy patterns disposed parallel to each other; and a first conductive pattern disposed between the first through fourth gate patterns, the first conductive pattern configured to contact the first and second dummy patterns to form a straight line.

In an example embodiment, the first and second dummy patterns are aligned with the first through fourth gate patterns and diagonally extend parallel to each other to contact sidewalls of the first and second gate patterns, respectively.

The semiconductor device further includes third and fourth dummy patterns. The at least one unit cell includes first, second and third unit cells, the second and third unit cells configured to electrically connect to the first unit cell, the second unit cell disposed on one selected from second end portions of the first unit cell and equal in phase to the first unit cell, at least one of the third and fourth dummy patterns configured to contact at least one of the first and second gate patterns of the second unit cell, the at least one of the third and fourth dummy patterns contacts at least one of the first and second dummy patterns configured to contact at least one of the first and second gate patterns of the first unit cell at a first cell boundary line between the first and second unit cells, and the third unit cell disposed on one selected from the first end portions of the first unit cell, the third unit cell including first through fourth active regions, wherein at least one of first, second, and third active regions and first, second, and fourth active regions are configured to contact at least one of first, second, and third active regions and first, second, and fourth active regions of the first unit cell at a second cell boundary line between the first and third unit cells.

The semiconductor device further includes a second conductive pattern disposed in the third unit cell, the second conductive pattern parallel to the first conductive pattern, wherein the first conductive pattern extends from the first unit cell to the second unit cell and is disposed between the first through fourth gate patterns of the first and second unit cells to contact the third and fourth dummy patterns, and the second conductive pattern has the same shape as the first conductive pattern and is disposed between the first through fourth gate patterns of the third unit cell to contact the first and second dummy patterns connected to the third unit cell.

In another example embodiment, the first and second dummy patterns are disposed on the first through fourth gate patterns to contact the first and second gate patterns, respectively, and disposed on at least one of the first and fourth gate patterns and at least one of the second and third gate patterns.

The semiconductor device further includes third and fourth dummy patterns. The at least one unit cell includes first, second and third unit cells, the second and third unit cells configured to electrically connect to the first unit cell, the second unit cell disposed on one selected from the second end portions of the first unit cell and equal in phase to the first unit cell, at least one of the third and fourth dummy patterns configured to contact at least one of the first and second gate patterns of the second unit cell, the at least one of the third and fourth dummy patterns contacting at least one of the first and second dummy patterns configured to contact at least one of the first and second gate patterns of the first unit cell at a first cell boundary line between the first and second unit cells, and the third unit cell disposed on one selected from the first end portions of the first unit cell, the third unit cell including first through fourth active regions, wherein at least one of first, second, and third active regions and first, second, and fourth active regions of the third unit cell are configured to contact at least one of first, second, and third active regions and first, second, and fourth active regions of the first unit cell at a second cell boundary line between the first and third unit cells.

The semiconductor device further includes a second conductive pattern disposed in the third unit cell, the second conductive pattern parallel to the first conductive pattern, wherein the first conductive pattern extends from the first unit cell to the second unit cell and is disposed between the first through fourth gate patterns of the first and second unit cells to contact the third and fourth dummy patterns, and the second conductive pattern has the same shape as the first conductive pattern and is disposed between the first through fourth gate patterns of the third unit cell to contact the first and second dummy patterns connected to the third unit cell.

In another example embodiment, the first and second dummy patterns are between the first through fourth gate patterns, protrude from top surfaces of the first and second gate patterns, and extend at least partially over the top surfaces of the first and second gate patterns to contact the first and second gate patterns, respectively.

The semiconductor device further includes third and fourth dummy patterns. The at least one unit cell includes first, second and third unit cells, the second and third unit cells configured to electrically connect to the first unit cell, the second unit cell disposed on one selected from the second end portions of the first unit cell and equal in phase to the first unit cell, at least one of the third and fourth dummy patterns configured to contact at least one of the first and second gate patterns of the second unit cell, the at least one of the third and fourth dummy patterns contacting at least one of the first and second dummy patterns configured to contact at least one of the first and second gate patterns of the first unit cell at a first cell boundary line between the first and second unit cells, and the third unit cell disposed on one selected from the first end portions of the first unit cell, the third unit cell including first through fourth active regions, wherein at least one of first, second, and third active regions and first, second, and fourth active regions of the third unit cell are configured to contact at least one of first, second, and third active regions and first, second, and fourth active regions of the first unit cell at a second cell boundary line between the first and third unit cells.

The semiconductor device further includes a second conductive pattern disposed in the third unit cell, the second conductive pattern parallel to the first conductive pattern, wherein the first conductive pattern extends from the first unit cell to the second unit cell and is disposed between the first through fourth gate patterns of the first and second unit cells to contact the third and fourth dummy patterns, and the second conductive pattern has the same shape as the first conductive pattern and is disposed between the first through fourth gate patterns of the third unit cell to contact the first and second dummy patterns connected to the third unit cell.

In another example embodiment of the inventive concepts, a semiconductor module includes a module substrate; and at least one semiconductor package structure electrically connected to the module substrate and including at least one semiconductor device, wherein the at least one semiconductor device includes a semiconductor cell structure disposed on a semiconductor substrate, and the semiconductor cell structure includes at least one unit cell, each unit cell including first through fourth active regions sequentially disposed in the at least one unit cell, the first through fourth active regions parallel to one another, first and second gate patterns disposed perpendicular to the first, third, and fourth active regions, the second gate pattern being aligned with the first gate pattern, wherein the first gate pattern is disposed on the first active region, and the second gate pattern is disposed on the third and fourth active regions, and third and fourth gate patterns disposed perpendicular to the first, second, and fourth active regions, the fourth gate pattern being aligned with the third gate pattern, wherein the third and fourth gate patterns are parallel to and facing the first and second gate patterns, the third gate pattern is disposed on the first and second active regions, and the fourth gate pattern is disposed on the fourth active region, first dummy patterns disposed on opposite edges of the at least one unit cell, the first dummy patterns being parallel to one another and configured to electrically connect to the first and fourth gate patterns, respectively; and a conductive pattern electrically connected to the first dummy patterns to form a straight line interposed between the first through fourth gate patterns.

In an example embodiment, the first dummy patterns are aligned with the first through fourth gate patterns in a vertical direction along a cross-section of the semiconductor cell structure and contact the first and fourth gate patterns, respectively. In another example embodiment, the first dummy patterns are disposed above the first through fourth gate patterns in a vertical direction along a cross-section of the semiconductor cell structure, contact the first and fourth gate patterns, respectively, and partially cover at least one of the first and third gate patterns and at least one of the second and fourth gate patterns.

In another example embodiment, the first dummy patterns are disposed between the first through fourth gate patterns in a vertical direction along a cross-section of the semiconductor cell structure, protrude from top surfaces of the first and fourth gate patterns and extend at least partially over the top surfaces of the first and fourth gate patterns, respectively.

In an example embodiment, the semiconductor module further includes a second dummy pattern. The at least one unit cell includes first, second and third unit cells, the second and third unit cells configured to electrically connect to the first unit cell, the second unit cell disposed in one of a lower end portion and an upper end portion of the first unit cell and equal in phase to the first unit cell, the second dummy pattern electrically connected to at least one of the first and fourth gate patterns of the second unit cell and configured to contact the first dummy pattern electrically connected to at least one of the first and fourth gate patterns of the first unit cell at a first cell boundary line between the first and second unit cells, and the third unit cell disposed on at least one of a left end portion and a right end portion of the first unit cell, the third unit cell including first through fourth active regions, wherein at least one of first, third, and fourth active regions and first, second, and fourth active regions of the third unit cell are configured to electrically connect to at least one of first, third, and fourth active regions and first, second, and fourth active regions of the first unit cell at a second cell boundary line between the first and third unit cells.

### BRIEF DESCRIPTION OF THE DRAWINGS

The foregoing and other features and advantages of the inventive concepts will be apparent from the more particular description of example embodiments of the inventive concepts, as illustrated in the accompanying drawings in which like reference characters refer to the same parts throughout the different views. The drawings are not necessarily to scale, emphasis instead being placed upon illustrating the principles of the inventive concepts. In the drawings:

FIG. 1 is a circuit diagram of a unit cell of a semiconductor cell structure according to an example embodiment;

FIG. 2 is a schematic diagram of a semiconductor cell structure including a plurality of unit cells of FIG. 1;

FIG. 3 is a layout diagram of a semiconductor cell structure of FIG. 2;

FIGS. 4 through 6 are cross-sectional views taken along lines I-I′ and II-II′ of FIG. 3, illustrating a method of forming a semiconductor cell structure;

FIG. 7 is a layout diagram of a semiconductor cell structure of FIG. 2;

FIGS. 8 through 10 are cross-sectional views taken along lines I-I′ and II-II′ of FIG. 7, illustrating a method of forming a semiconductor cell structure;

FIG. 11 is a layout diagram of a semiconductor cell structure of FIG. 2;

FIGS. 12 and 13 are cross-sectional views taken along lines I-I′ and II-II′ of FIG. 11, illustrating a method of forming a semiconductor cell structure;

FIG. 14 is a plan view of a semiconductor module according to an example embodiment; and

FIG. 15 is a plan view of a processor-based system according to an example embodiment.

### DETAILED DESCRIPTION OF EXAMPLE EMBODIMENTS

Various example embodiments will now be described more fully with reference to the accompanying drawings in which some example embodiments are shown. These inventive concepts may, however, be embodied in different forms and should not be construed as limited to the example embodiments set forth herein. Rather, these example embodiments are provided so that this disclosure is thorough and complete and fully conveys the inventive concepts to those skilled in the art.

It will be understood that, although the terms “semiconductor substrate,” “insulating pattern,” “gate pattern,” and “dummy pattern” may be used herein to describe various elements, components, regions, layers and/or sections, these elements, components, regions, layers and/or sections should not be limited by these terms. These terms are only used to distinguish one element, component, region, layer or section from another region, layer or section. As used herein, the term “at least one” includes any and all combinations of one or more of the associated listed items. Meanwhile, spatially relative terms, such as “selected,” “upper end portion,” “lower end portion,” “right end portion,” “left end portion,” and “on” and the like, which are used herein for ease of description to describe one element or feature's relationship to another element(s) or feature(s) as illustrated in the figures, should be interpreted similarly. The terminology used herein is for the purpose of describing particular embodiments only and is not intended to be limiting of the inventive concepts.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes”, and/or “including” when used in this application, specify the presence of stated features, integers, steps, operations, elements, and/or components, but do not preclude the presence or addition of one or more other features, integers, steps, operations, elements, components, and/or groups thereof.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Example embodiments of the inventive concepts are described herein with reference to (plan and) cross-section illustrations that are schematic illustrations of idealized embodiments of the inventive concepts. As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing. Thus, the elements illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

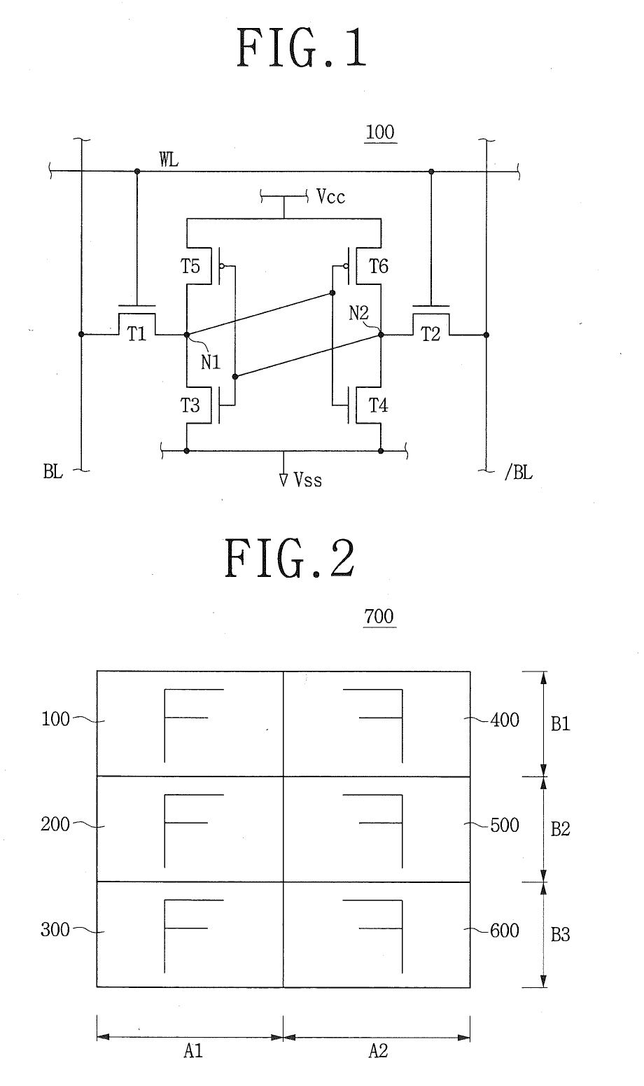

A semiconductor cell structure according to example embodiments of the inventive concepts will be described in further detail with reference to the accompanying drawings. FIG. 1 is a circuit diagram of a unit cell in a semiconductor cell structure according to an example embodiment.

Referring to FIG. 1, a unit cell 100 according to an example embodiment may be defined by circuitry between intersections of a word line WL, and first and second bit lines BL and /BL. The word line WL may intersect the first and second bit lines BL and /BL. First through sixth transistors T1, T2, T3, T4, T5, and T6 may be disposed between the word line WL and the first and second bit lines BL and /BL. A source region or drain region (not shown) of the first transistor T1 may be electrically connected to the first bit line BL.

A source region or drain region (not shown) of the second transistor T2 may be electrically connected to the second bit line /BL. Each of the first and second transistors T1 and T2 may be an N-channel metal-oxide-semiconductor field effect transistor (MOSFET). A flip-flop circuit may be disposed between the first and second transistors T1 and T2. The flip-flop circuit may be interposed between first and second power sources Vss and Vcc. The flip-flop circuit may include first and second inverters.

The first inverter may include the third and fifth transistors T3 and T5. One end of the third and fifth transistors T3 and T5 may be electrically connected to the drain or source region of the first transistor T1 through an output node N1 of the first inverter. The other end of the third and fifth transistors T3 and T5 may be connected to the first and second power sources Vss and Vcc, respectively. The second inverter may include the fourth and sixth transistors T4 and T6. One end of the fourth and sixth transistors T4 and T6 may be electrically connected to the drain or source region of the second transistor T2 through an output node N2 of the second inverter.

The other end of the fourth and sixth transistors may be connected to the first and second power sources Vss and Vcc, respectively. In this case, the output nodes N1 and N2 of the first and second inverters may be electrically connected to input nodes of the second and first inverters, respectively. Each of the third and fourth transistors may be an N-channel MOSFET. Each of the fifth and sixth transistors may be a P-channel MOSFET.

FIG. 2 is a schematic diagram of a semiconductor cell structure including a plurality of unit cells of FIG. 1. Referring to FIG. 2, a semiconductor cell structure 700 according to an example embodiment may include first through sixth unit cells 100, 200, 300, 400, 500, and 600, which are arranged 2-dimensionally in columns and rows. The first through third unit cells 100, 200, and 300 may have first through third areas of A1×B1, A1×B2, and A1×B3, respectively, in columns and selected rows. The second and third unit cells 200 and 300 may be equal in phase to the first unit cell 100 and be disposed in the semiconductor cell structure 700.

A length B1 of the first unit cell 100 may be equal to each of lengths B2 and B3 of the second and third unit cells 200 and 300. The fourth through sixth unit cells 400, 500, and 600 may have fourth through sixth areas of A2×B1, A2×B2, and A2×B3, respectively, in the columns and the remaining rows. The fourth through sixth unit cells may be mirror images of the first through third unit cells, respectively, with respect to the selected rows.

A width A2 of the fourth unit cell 400 may be equal to a width A1 of the first unit cell 100. In this case, the first and fourth unit cells 100 and 400 may not protrude toward each other along a selected row but contact each other sufficiently by as much as the length B1. The second and fifth unit cells 200 and 500 may not protrude toward each other along one of the remaining rows but contact each other sufficiently by as much as the length B2, and the third and sixth unit cells 300 and 600 may not protrude toward each other along the other one of the remaining rows but contact each other sufficiently by as much as the length B3.

In addition, the first and fourth unit cells 100 and 400 may not protrude from the second and fifth unit cells 200 and 500 along columns but sufficiently contact the second and fifth unit cells 200 and 500 by a width A1+A2, respectively. The second and fifth unit cells 200 and 500 may not protrude from the third and sixth units 300 and 600 along columns but sufficiently contact the third and sixth unit cells 300 and 600 by the width A1+A2, respectively. Thus, the first through sixth unit cells 100, 200, 300, 400, 500, and 600 may not protrude from one another but be aligned with one another along columns and rows.

The first through sixth unit cells 100, 200, 300, 400, 500, and 600 may be repetitively and periodically arranged along the columns and rows of the semiconductor cell structure 700.

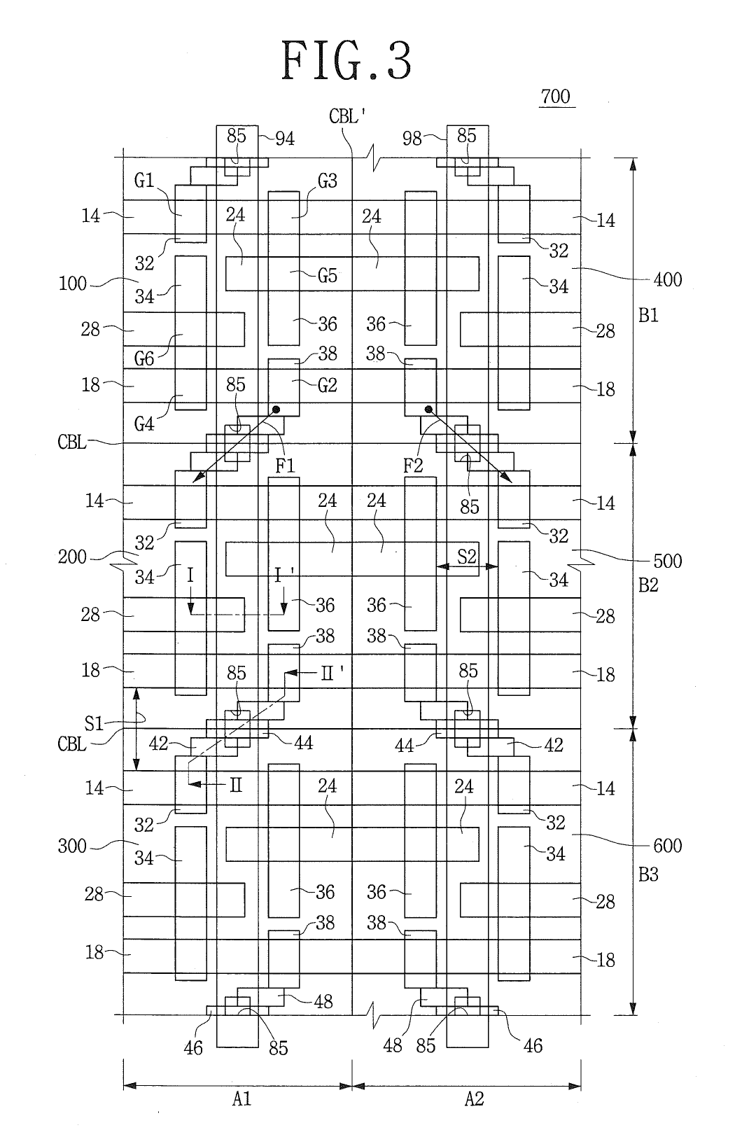

FIG. 3 is a schematic layout diagram of the semiconductor cell structure of FIG. 2, according to embodiments. For the purpose of faithful disclosure of the inventive concepts according to example embodiments, the semiconductor cell structure is schematically illustrated in the layout diagram.

Referring to FIG. 3, the semiconductor cell structure 700 according to the example embodiment of inventive concepts may include the first unit cell 100 of FIG. 2. The first unit cell 100 may have a predetermined or given area of A1×B1 in the semiconductor cell structure 700. The first unit cell 100 may be a unit cell for an SRAM. The first unit cell 100 may include first and second active regions 14 and 18 that are sequentially disposed parallel to each other. The first and second active regions 14 and 18 may contact first end portions of the first unit cell 100.

The first end portions may be right and left end portions of the first unit cell 100 parallel to the width A1. Third and fourth active regions 24 and 28 may be disposed between the first and second active regions 12 and 14. The third and fourth active regions 24 and 28 may be sequentially disposed parallel to the first and second active regions 14 and 18. The third and fourth active regions 24 and 28 may extend toward each other from the first end portions of the first unit cell 100.

A first gate pattern 32 may be disposed on the first active region 14. The first gate pattern 32 may be disposed perpendicular to the first active region 14. An intersection between the first active region 14 and the first gate pattern 32 may define a gate G1 of the first transistor T1 of FIG. 1. A second gate pattern 34 may be disposed on the second and fourth active regions 18 and 28. The second gate pattern 34 may be disposed perpendicular to the second and fourth active regions 18 and 28. Intersections between the second and fourth active regions 18 and 28 and the second gate pattern 34 may respectively define gates G4 and G6 of the fourth and sixth transistors T4 and T6 of FIG. 1.

The second gate pattern 34 may be disposed on the same straight line as the first gate pattern 32. A third gate pattern 36 may be disposed on the first and third active regions 14 and 24. The third gate pattern 36 may be disposed perpendicular to the first and third active regions 14 and 24. Intersections between the first and third active regions 14 and 24 and the third gate pattern 36 may respectively define gates G3 and G5 of the third and fifth transistors T3 and T5 of FIG. 1. A fourth gate pattern 38 may be disposed on the second active region 18.

The fourth gate pattern 38 may be disposed perpendicular to the second active region 18. An intersection between the second active region 18 and the fourth gate pattern 38 may define a gate G2 of the second transistor T2 of FIG. 1. The fourth gate pattern 38 may be disposed on the same straight line as the third gate pattern 36. The third and fourth gate patterns 36 and 38 may be disposed parallel to the first and second gate patterns 32 and 34. The first and fourth gate patterns 32 and 38 may be disposed diagonally opposite each other.

The second and third gate patterns 34 and 36 may be partially disposed opposite each other and parallel to each other. The gates G1, G2, G3, G4, G5, and G6 may control flow of charges in the first through sixth transistors T1, T2, T3, T4, T5, and T6 of FIG. 1 during the drive of the semiconductor cell structure 700. First dummy patterns 42 and 44 may be in contact with the first gate pattern 32. The first dummy patterns 42 and 44 may be disposed on an edge of the first unit cell 100. Second dummy patterns 46 and 48 may be in contact with the fourth gate pattern 38.

The second dummy patterns 46 and 48 may be disposed on an edge of the first unit cell 100 opposite the first dummy patterns 42 and 44. The second dummy patterns 46 and 48 may diagonally extend parallel to the first dummy patterns 42 and 44. The first and second dummy patterns 42, 44, 46, and 48 may contact second end portions perpendicular to the first end portions between the first through fourth gate patterns 32, 34, 36, and 38. The second end portions may be lower and upper end portions of the first unit cell 100. Second and third unit cells 200 and 300 may be sequentially disposed under the first unit cell 100 as shown in FIG. 2.

Each of the second and third unit cells 200 and 300 may be equal in phase to the first unit cell 100. Each of the second and third unit cells 200 and 300 may have the same components as the first unit cell 100. The second dummy patterns 46 and 48 of the first unit cell 100 and the first dummy patterns 42 and 44 of the second unit cell 200 may be disposed between the fourth gate pattern 38 of the first unit cell 100 and the first gate pattern 32 of the second unit cell 200. The second dummy patterns 46 and 48 of the first unit cell 100 and the first dummy patterns 42 and 44 of the second unit cell 200 may diagonally contact each other along a first direction F1 at a first cell boundary line CBL between the first and second unit cells 100 and 200.

The second dummy patterns 46 and 48 of the second unit cell 200 and the first dummy patterns 42 and 44 of the third unit cell 300 may be disposed between the fourth gate pattern 38 of the second unit cell 200 and the first gate pattern 32 of the third unit cell 300. The second dummy patterns 46 and 48 of the second unit cell 200 and the first dummy patterns 42 and 44 of the third unit cell 300 may diagonally contact each other along the first direction F1 at the first cell boundary line CBL between the second and third unit cells 200 and 300. The first through third unit cells 100, 200, and 300 may not protrude from one another along the first cell boundary line CBL but be completely aligned with one another.

In this case, in the first and second unit cells 100 and 200 or the second and third unit cells 200 and 300, a distance S1 between the first and second active regions 14 and 18 disposed adjacent to the first cell boundary line CBL may be smaller than in the conventional art. The first and second unit cells 100 and 200 or the second and third unit cells 200 and 300 may be completely aligned with each other along the first cell boundary line CBL and have the first and second dummy patterns 42, 44, 46, and 48 between the first through fourth gate patterns 32, 34, 36, and 38.

Similar to FIG. 2, the first through third unit cells 100, 200, and 300 may contact the fourth through sixth unit cells 400, 500, and 600, respectively, at a second cell boundary line CBL′ between the first through third unit cells 100, 200, and 300 and the fourth through sixth unit cells 400, 500, and 600. The fourth through sixth unit cells 400, 500, and 600 may be mirror images of the first through third unit cells 100, 200, and 300 on the basis of the second cell boundary line CBL′. The fourth through sixth unit cells 400, 500, and 600 may not protrude from one another along the first cell boundary line CBL but be completely aligned with one another.

Each of the fourth through sixth unit cells 400, 500, and 600 may have the same components as the first unit cell 100. The first, second, and third active regions 14, 18, and 24 of the fourth unit cell 400 may contact the first, second, and third active regions 14, 18, and 24 of the first unit cell 100, respectively, at the second cell boundary line CBL′ between the first and fourth unit cells 100 and 400. The first, second, and third active regions 14, 18, and 24 of the fifth unit cell 500 may contact the first, second, and third active regions 14, 18, and 24 of the second unit cell 200, respectively, at the second cell boundary line CBL′ between the second and fifth unit cells 200 and 500.

The first, second, and third active regions 14, 18, and 24 of the sixth unit cell 600 may contact the first, second, and third active regions 14, 18, and 24 of the third unit cell 300, respectively, at the second cell boundary line CBL′ between the third and sixth unit cells 300 and 600. The second dummy patterns 46 and 48 of the fourth unit cell 400 may diagonally contact the first dummy patterns 42 and 44 of the fifth unit cell 500 along a second direction F2 at the first cell boundary line CBL between the fourth and fifth unit cells 400 and 500. The second dummy patterns 46 and 48 of the fifth unit cell 500 may diagonally contact the first dummy patterns 42 and 44 of the sixth unit cell 600 along the second direction F2 at the first cell boundary line CBL between the fifth and sixth unit cells 500 and 600.

Diagonal lines in the first and second directions F1 and F2 may have loci which extend from the fourth gate patterns 38 of the first and fourth unit cells 100 and 400 or the second and fifth unit cells 200 and 500 and move farther away from each other. In the fourth and fifth unit cells 400 and 500 or the fifth and sixth unit cells 500 and 600, the distance S1 between the first and second active regions 14 and 18 disposed adjacent to the first cell boundary line CBL may be smaller than in the conventional art. The fourth through sixth unit cells 400, 500, and 600 may be repetitively and periodically arranged along with the first through third unit cells 100, 200, and 300 along columns and rows of the semiconductor cell structure 700.

The first through fourth active regions 14, 18, 24, and 28 may increase pattern fidelity to the corresponding photomask thereof more than in the conventional art due to a uniform alignment relationship of the first through sixth unit cells 100, 200, 300, 400, 500, and 600. The first through fourth gate patterns 32, 34, 36, and 38 may increase pattern fidelity to the corresponding photomask thereof more than in the conventional art due to the uniform alignment relationship of the first through sixth unit cells 100, 200, 300, 400, 500, and 600. The first and second dummy patterns 42, 44, 46, and 48 may increase pattern fidelity to the corresponding photomask thereof more than in the conventional art due to the uniform alignment relationship of the first through sixth unit cells 100, 200, 300, 400, 500, and 600.

First and second conductive patterns 94 and 98 may be disposed on the first through sixth unit cells 100, 200, 300, 400, 500, and 600. The first conductive pattern 94 may be disposed on the first through third unit cells 100, 200, and 300. The first conductive pattern 94 may be disposed between the first through fourth gate patterns 32, 34, 36, and 38 of the first through third unit cells 100, 200, and 300. The first conductive pattern 94 may have a substantially elongate shape. The first conductive pattern 94 may have a straight-line shape.

The first conductive pattern 94 may be electrically connected to the first and second dummy patterns 42, 44, 46, and 48 of the first and second unit cells 100 and 200 through the connection hole 85 at the first cell boundary line CBL between the first and second unit cells 100 and 200 and/or adjacent to the first cell boundary line CBL. The first conductive pattern 94 may be electrically connected to the first and second dummy patterns 42, 44, 46, and 48 of the second and third unit cells 200 and 300 through the connection hole 85 at the first cell boundary line CBL between the second and third unit cells 200 and 300 and/or adjacent to the first cell boundary line CBL.

The second conductive pattern 98 may be disposed on the fourth through sixth unit cells 400, 500, and 600 parallel to the first conductive pattern 94. The second conductive pattern 98 may be disposed between the first through fourth gate patterns 32, 34, 36, and 38 of the fourth through sixth unit cells 400, 500, and 600. The second conductive pattern 98 may have a substantially elongate shape. The second conductive pattern 98 may have a straight-line shape. The second conductive pattern 98 may be electrically connected to the first and second dummy patterns 42, 44, 46, and 48 of the fourth and fifth unit cells 400 and 500 through the connection hole 85 at the first cell boundary line CBL between the fourth and fifth unit cells 400 and 500 and/or adjacent to the first cell boundary line CBL.

The second conductive pattern 98 may be electrically connected to the first and second dummy patterns 42, 44, 46, and 48 of the fifth and sixth unit cells 500 and 600 through the connection hole 85 at the first cell boundary line CBL between the fifth and sixth unit cells 500 and 600 and/or adjacent to the first cell boundary line CBL. The connection hole 85 of each of the first through sixth unit cells 100, 200, 300, 400, 500, and 600 may expose the first or second dummy pattern 42 or 44, and a peripheral region of the first or second dummy pattern 42 or 44. The connection hole 85 of each of the first through sixth unit cells 100, 200, 300, 400, 500, and 600 may expose only the first or second dummy pattern 42 or 44.

A width of the first and second conductive patterns 94 and 98 may be smaller in size than a distance S2 between the first and third gate patterns 32 and 36, a distance S2 between the second and third gate patterns 34 and 36, and a distance S2 between the second and fourth gate patterns 34 and 38 of the first through sixth unit cells 100, 200, 300, 400, 500, and 600. The first and second conductive patterns 94 and 98 may be periodically and repetitively arranged along columns and rows of the semiconductor cell structure 700.

The first and second conductive patterns 94 and 98 may have lower electric resistances than in the conventional art on the first through sixth unit cells 100, 200, 300, 400, 500, and 600, because the first and second conductive patterns 94 and 98 have an elongate shape instead of a conventional zigzag shape. In addition, the first and second conductive patterns 94 and 98 may increase pattern fidelity to the corresponding photomasks thereof more than in the conventional art due to the uniform alignment relationship of the first through sixth unit cells 100, 200, 300, 400, 500, and 600. The first and second conductive patterns 94 and 98 may be the word lines WL of FIG. 1.

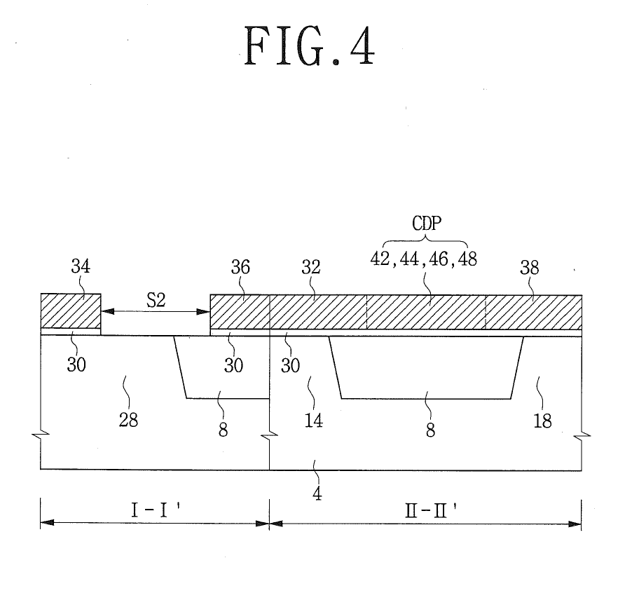

FIGS. 4 through 6 are cross-sectional views taken along lines I-II and II-II′ of FIG. 3, illustrating a method of forming a semiconductor cell structure. Referring to FIG. 4, according to an example embodiment of inventive concepts, an inactive region 8 may be formed on a semiconductor substrate 4. The semiconductor substrate 4 may include single crystalline silicon, polycrystalline silicon, and/or another material. The inactive region 8 may include at least one insulating material. The inactive region 8 may also be formed to define active regions 14, 18, and 28. The inactive region 8 may be formed to define the active region 24 of FIG. 3. Insulating patterns 30 may be formed on the inactive region 8 and the active regions 14, 18, and 28. The insulating patterns 30 may or may not expose the semiconductor substrate 4.

The insulating patterns 30 may include an insulating material having a different etch rate from the semiconductor substrate 4 and/or the inactive region 8. First through fourth gate patterns 32, 34, 36, and 38 may be formed on the insulating patterns 30. The second and third gate patterns 34 and 36 may be formed to a predetermined or given distance S2 apart from each other. The first through fourth gate patterns 32, 34, 36, and 38 may include doped polysilicon. Each of the first through fourth gate patterns 32, 34, 36, and 38 may include a conductive material other than doped polysilicon.

Each of the first through fourth gate patterns 32, 34, 36, and 38 may also include a conductive material and an insulating material that are sequentially stacked. First and second dummy patterns 42, 44, 46, and 48 may be formed between the first and fourth gate patterns 32 and 38. The first and second dummy patterns 42, 44, 46, and 48 may be formed at the same level as the first through fourth gate patterns 32, 34, 36, and 38. The first and second dummy patterns 42, 44, 46, and 48 may include the same material as or a different material from the first through fourth gate patterns 32, 34, 36, and 38. The first and second dummy patterns 42, 44, 46, and 48 may constitute a cell dummy pattern CDP.

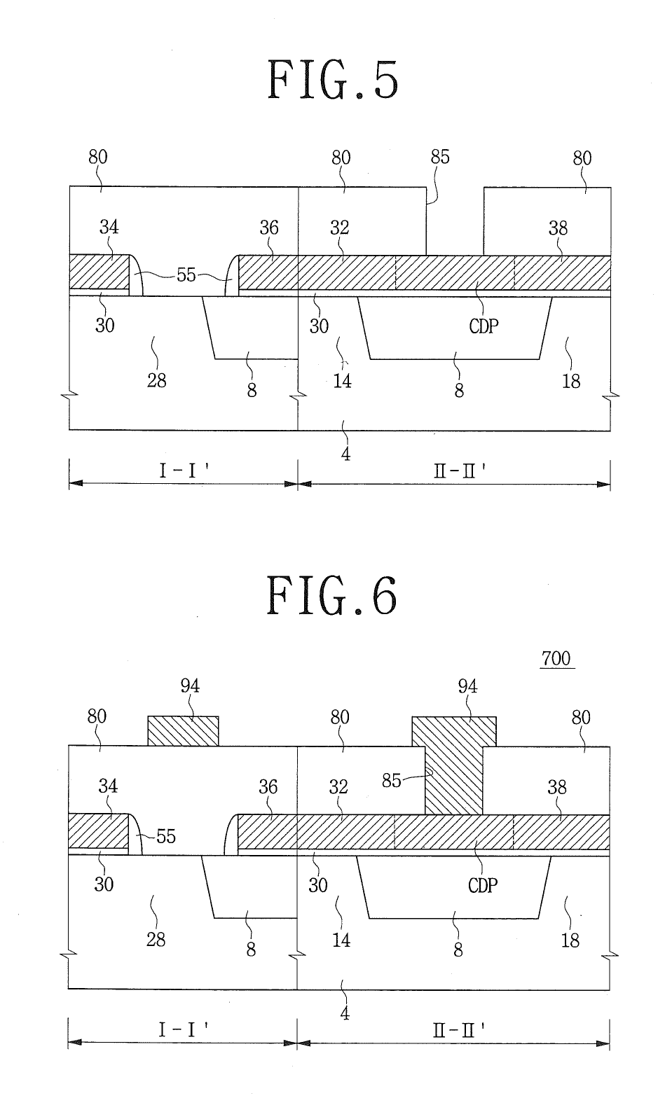

Referring to FIG. 5, according to an example embodiment of the inventive concepts, spacers 55 may be formed on sidewalls of the insulating patterns 30 and the first through fourth gate patterns 32, 34, 36, and 38. When the insulating pattern 30 do not expose the semiconductor substrate 4, the spacers 55 may be formed only on the sidewalls of the first through fourth gate patterns 32, 34, 36, and 38 and the cell dummy pattern CDP. The spacers 55 may include an insulating material having a different etch rate from the first through fourth gate patterns 32, 34, 36, and 38. A protection layer 80 may be formed on the semiconductor substrate 4 to cover the first through fourth gate patterns 32, 34, 36, and 38, the spacers 55, and the cell dummy pattern CDP.

The protection layer 80 may include an insulating material having a different etch rate from the semiconductor substrate 4, the inactive region 8, the first through fourth gate patterns 32, 34, 36, and 38 and the spacers 55. A connection hole 85 may be formed in the protection layer 80. The connection hole 85 may be formed to expose the cell dummy pattern CDP. In this case, since the connection hole 85 is formed as shown in FIG. 3, the connection hole 85 may expose the cell dummy pattern CDP and the protection layer 80 or the cell dummy pattern CDP, the inactive region 8, and the first insulating layer 80.

Referring to FIG. 6, according to an example embodiment of the inventive concepts, a first conductive pattern 94 may be formed in the connection hole 85. The first conductive pattern 94 may be formed on the protection layer 80 to fill the connection hole 85. The first conductive pattern 94 may be formed on the semiconductor substrate 4 simultaneously with the second conductive pattern 98 of FIG. 3. The first conductive pattern 94 may include at least one conductive material. The semiconductor substrate 4, the first through fourth gate patterns 32, 34, 36, and 38, and the first conductive pattern 94 may constitute the semiconductor cell structure 700.

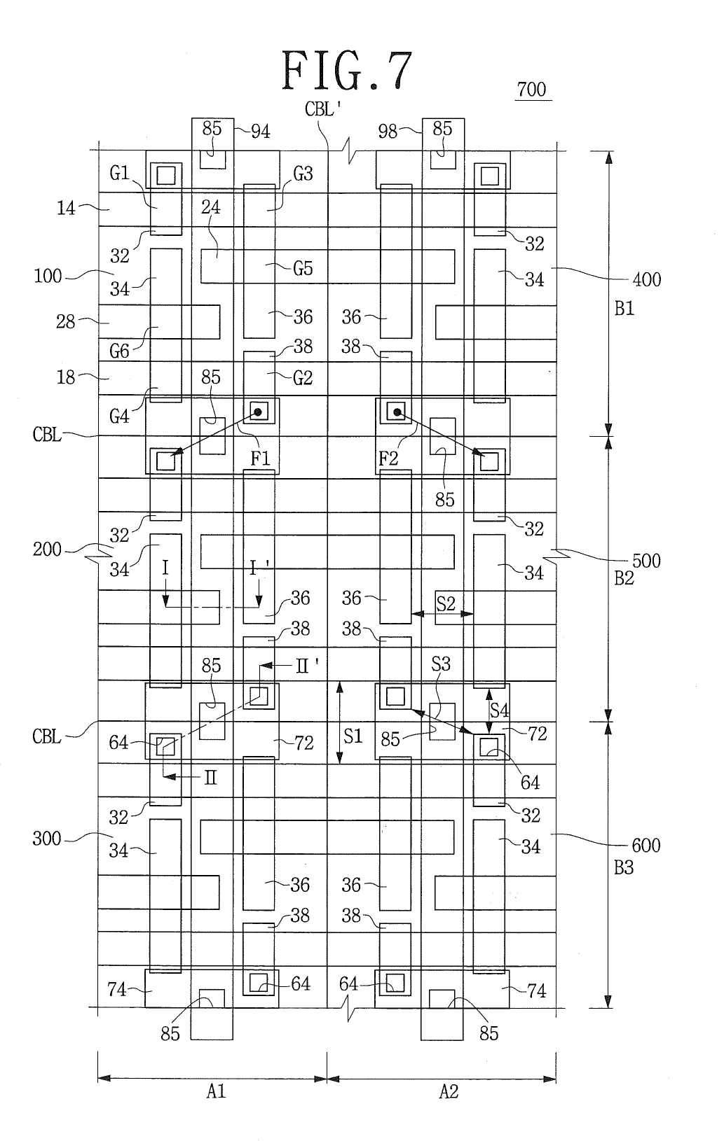

FIG. 7 is a layout diagram of a semiconductor cell structure of FIG. 2. In FIG. 7, the same reference numerals are used to denote the same components as in FIG. 3. Referring to FIG. 7, a semiconductor cell structure 700 according to embodiments may include first through sixth unit cells 100, 200, 300, 400, 500, and 600 of FIG. 2. The first through sixth unit cells 100, 200, 300, 400, 500, and 600 may have predetermined or given areas of A1×B1, A1×B2, A1×B3, A2×B1, A2×B2, and A2×B3, respectively, in the semiconductor cell structure 700. The first through sixth unit cells 100, 200, 300, 400, 500, and 600 may have almost the same components as the first through sixth unit cells 100, 200, 300, 400, 500, and 600 of FIG. 3.

In this case, the first through third unit cells 100, 200, and 300 may be equal in phase to one another. The fourth through sixth unit cells 400, 500, and 600 may be equal in phase to one another. The fourth through sixth unit cells 400, 500, and 600 may be minor images of the first through third unit cells 100, 200, and 300, respectively. However, the first and second dummy patterns 72 and 74 of each of the first through sixth unit cells 100, 200, 300, 400, 500, and 600 may have a different shape from the first and second dummy patterns 42, 44, 46, and 48 of each of the first through sixth unit cells 100, 200, 300, 400, 500, and 600 of FIG. 3.

The first dummy pattern 72 of the first unit cell 100 may be disposed on an edge of the first unit cell 100. The first dummy pattern 72 of the first unit cell 100 may or may not be disposed on the third gate pattern 36 to partially cover the first gate pattern 32. The first dummy pattern 72 of the first unit cell 100 may be electrically connected to the first gate pattern 32 through a through hole 64. The second dummy pattern 74 of the first unit cell 100 may be disposed on an edge of the first unit cell 100 opposite the first dummy pattern 72. The second dummy pattern 74 of the first unit cell 100 may or may not be disposed on the second gate pattern 34 to partially cover the fourth gate pattern 38. The first and second dummy gate patterns 72 and 74 of the first unit cell 100 may be disposed parallel to each other.

The second dummy pattern 74 of the first unit cell 100 may be electrically connected to the fourth gate pattern 38 through the through hole 64. The first and second dummy patterns 72 and 74 of the first unit cell 100 may be exposed through the second end portions of FIG. 3 more than the first and second dummy patterns 42, 44, 46, and 48 of the first unit cell 100 of FIG. 3. Like in the first unit cell 100, the first and second dummy patterns 72 and 74 may be disposed along with the through holes 64 in each of the second through sixth unit cells 200, 300, 400, 500, and 600. The second dummy pattern 74 of the first unit cell 100 may contact the first dummy pattern 72 of the second unit cell 200 at a first cell boundary line CBL between the first and second unit cells 100 and 200.

The through hole 64 disposed on the fourth gate pattern 38 of the first unit cell 100 may face the through hole 64 disposed on the first gate pattern 32 of the second unit cell 200 along a first direction F 1. The second dummy pattern 74 of the second unit cell 200 may contact the first dummy pattern 72 of the third unit cell 300 at a first cell boundary line CBL between the second and third unit cells 200 and 300. The through hole 64 disposed on the fourth gate pattern 38 of the second unit cell 200 may face the through hole 64 disposed on the first gate pattern 32 of the third unit cell 300 along the first direction F1.

The second dummy pattern 74 of the fourth unit cell 400 may contact the first dummy pattern 72 of the fifth unit cell 500 at a first cell boundary line CBL between the fourth and fifth unit cells 400 and 500. The through hole 64 disposed on the fourth gate pattern 38 of the fourth unit cell 400 may face the through hole 64 disposed on the first gate pattern 32 of the fifth unit cell 500 along a second direction F2. The second dummy pattern 74 of the fifth unit cell 500 may contact the first dummy pattern 72 of the sixth unit cell 600 at a first cell boundary line CBL between the fifth and sixth unit cells 500 and 600.

The through hole 64 disposed on the fourth gate pattern 38 of the fifth unit cell 500 may face the through hole 64 disposed on the first gate pattern 32 of the sixth unit cell 600 along the second direction F2. The first and second dummy patterns 72 and 74 may increase pattern fidelity to the corresponding photomask thereof more than in the conventional art due to a uniform alignment relationship of the first through sixth unit cells 100, 200, 300, 400, 500, and 600. Since the first and second dummy patterns 72 and 74 are disposed on the first through fourth gate patterns 32, 34, 36, and 38, a distance S3 between the first and fourth gate patterns 32 and 38 in the first through sixth unit cells 100, 200, 300, 400, 500, and 600 may be reduced more than in the conventional art in consideration of a design rule related to a distance S4 between the first and fourth gate patterns 32 and 38.

A distance S1 between the first and second active regions 14 and 18 in the first through sixth unit cells 100, 200, 300, 400, 500, and 600 may be reduced more than in the conventional art. The first through sixth unit cells 100, 200, 300, 400, 500, and 600 may have the first and second conductive patterns 94 and 98 of FIG. 3. The first conductive pattern 94 may be disposed on the first through third unit cells 100, 200, and 300. The first conductive pattern 94 may be electrically connected to the first and second dummy patterns 72 and 74 of the first through third unit cells 100, 200, and 300 through connection holes 85.

The second conductive pattern 98 may be disposed on the fourth through sixth unit cells 400, 500, and 600. The second conductive pattern 98 may be electrically connected to the first and second dummy patterns 72 and 74 of the fourth through sixth unit cells 400, 500, and 600 through the connection holes 85. As in FIG. 3, each of the first and second conductive patterns 94 and 98 may have the same arrangement structure with respect to the first through fourth gate patterns 32, 34, 36, and 38 of the first through sixth unit cells 100, 200, 300, 400, 500, and 600.

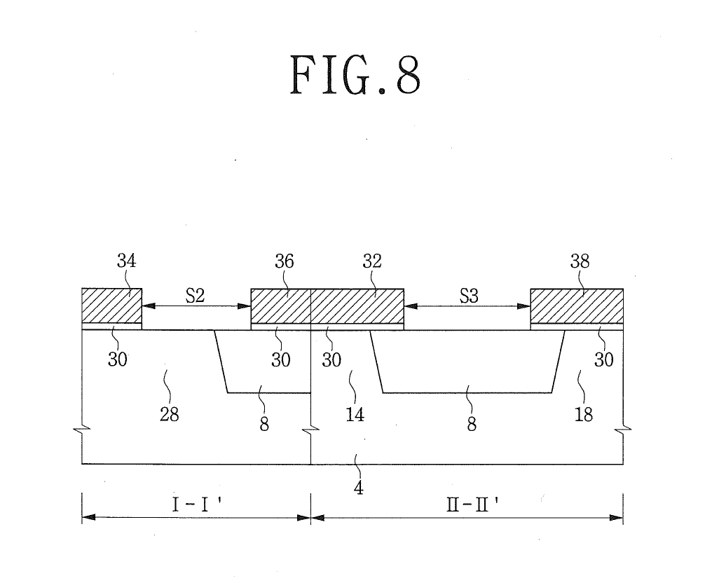

FIGS. 8 through 10 are cross-sectional views taken along lines I-I′ and II-II′ of FIG. 7, illustrating a method of forming a semiconductor cell structure. In FIGS. 8 through 10, the same reference numerals are used to denote the same components as in FIGS. 4 through 6.

Referring to FIG. 8, according to an example embodiment of the inventive concepts, a semiconductor substrate 4 may be prepared. An inactive region 8 and active regions 14, 18, and 28 may be formed on the semiconductor substrate 4. Insulating patterns 30 may be formed on the semiconductor substrate 4. First through fourth gate patterns 32, 34, 36, and 38 may be formed on the insulating patterns 30, respectively. The first and fourth gate patterns 32 and 38 may be formed at a predetermined or given distance S3 to diagonally face each other as shown in FIG. 7.

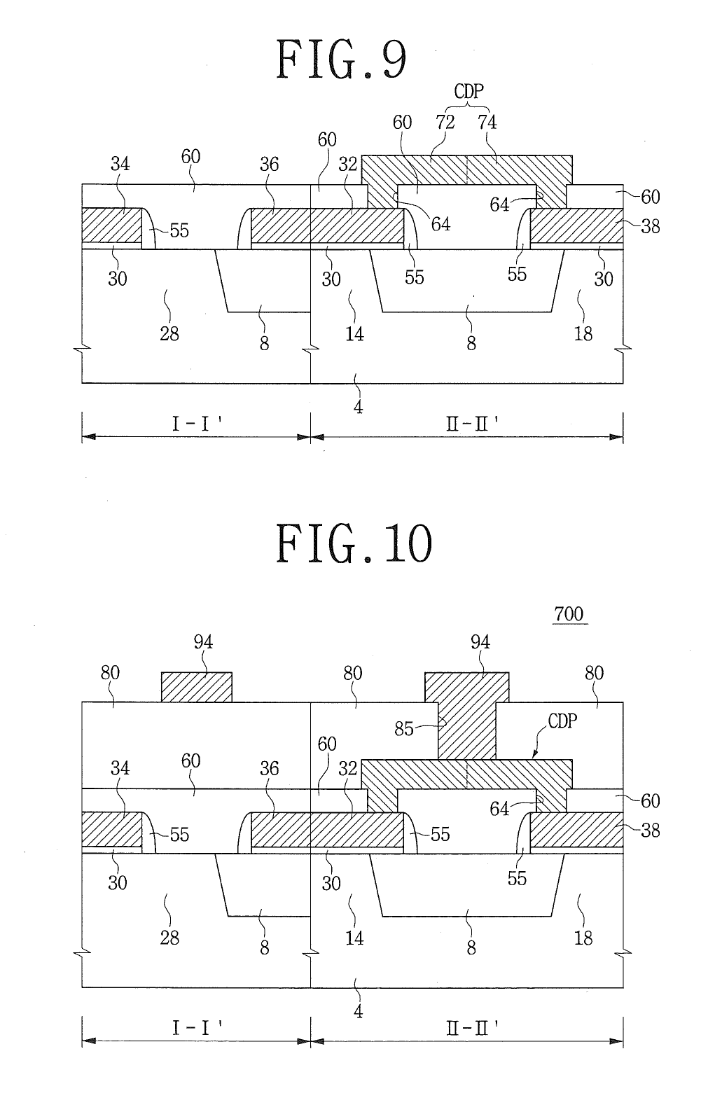

Referring to FIG. 9, according to an example embodiment of the inventive concepts, spacers 55 may be formed on sidewalls of the insulating patterns 30 and the first through fourth gate patterns 32, 34, 36, and 38. An insulating layer 60 may be formed on the semiconductor substrate 4 to cover the first through fourth gate patterns 32, 34, 36, and 38 and the spacers 55. The insulating layer 60 may include an insulating material having a different etch rate from the inactive region 8, the first through fourth gate patterns 32, 34, 36, and 38 and the spacers 55. Through holes 64 may be formed in the insulating layer 60. The through holes 64 may be formed to expose the first and fourth gate patterns 32 and 38.

First and second dummy patterns 72 and 74 may be formed in the through holes 64, respectively. The first and second dummy patterns 72 and 74 may be formed on the insulating layer 60 to fill the through holes 64. The first and second dummy patterns 72 and 74 may be formed on the insulating layer 60 between the through holes 64 to contact each other. The first and second dummy patterns 72 and 74 may include the same material as or a different material from the first through fourth gate patterns 32, 34, 36, and 38. The first and second dummy patterns 72 and 74 may constitute a cell dummy pattern CDP.

Referring to FIG. 10, according to an example embodiment of the inventive concepts, a protection layer 80 may be formed on the insulating layer 60 to cover the first and second dummy patterns 72 and 74. A connection hole 85 may be formed in the protection layer 80. The connection hole 85 may be formed to expose the cell dummy pattern CDP. A first conductive pattern 94 may be formed in the connection hole 85. The first conductive pattern 94 may be formed on the insulating layer 80 to fill the connection hole 85. The semiconductor substrate 4, the first through fourth gate patterns 32, 34, 36, and 38, and the first conductive pattern 94 may constitute the semiconductor cell structure 700.

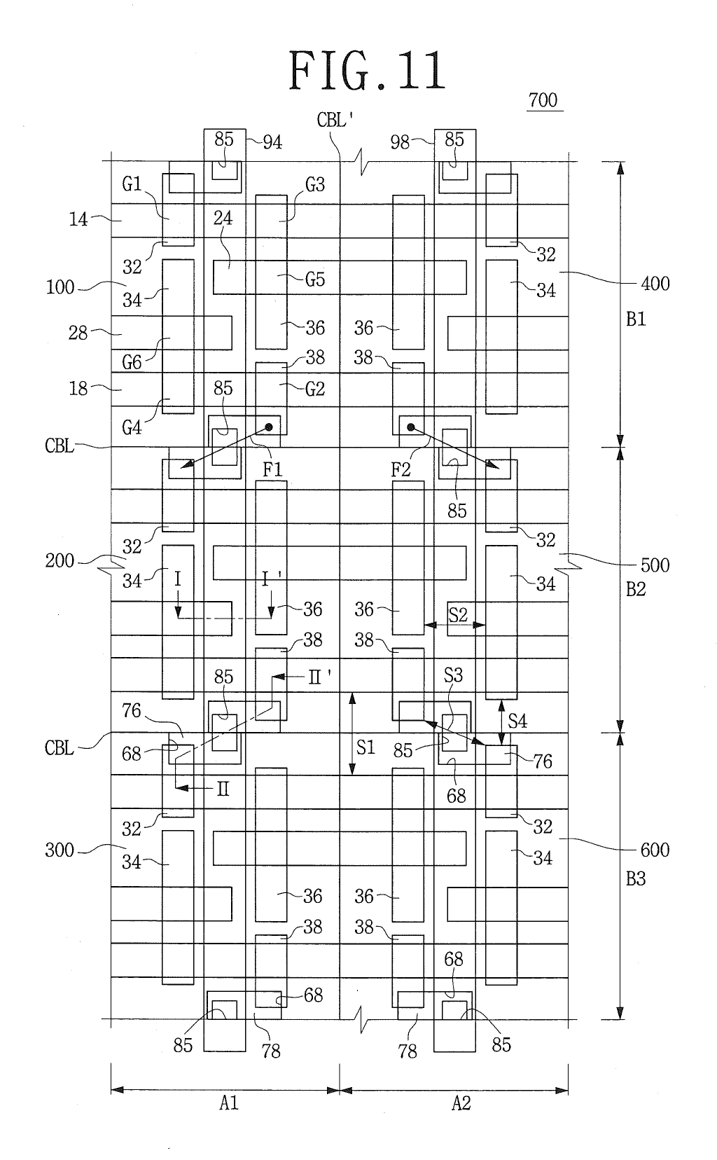

FIG. 11 is a layout diagram of a semiconductor cell structure of FIG. 2. In FIG. 11, the same reference numerals are used to denote the same components as in FIG. 3. Referring to FIG. 11, a semiconductor cell structure 700 according to embodiments may include the first through sixth unit cells 100, 200, 300, 400, 500, and 600 of FIG. 2. The first through sixth unit cells 100, 200, 300, 400, 500, and 600 may have predetermined or given areas of A1×B1, A1×B2, A1×B3, A2×B1, A2×B2, and A2×B3, respectively, in the semiconductor cell structure 700. The first through sixth unit cells 100, 200, 300, 400, 500, and 600 may have almost the same components as the first through sixth unit cells 100, 200, 300, 400, 500, and 600 of FIG. 3.

In this case, the first through third unit cells 100, 200, and 300 may be equal in phase to each other. The fourth through sixth unit cells 400, 500, and 600 may be equal in phase to each other. The fourth through sixth unit cells 400, 500, and 600 may be mirror images of the first through third unit cells 100, 200, and 300, respectively. However, dummy patterns 76 and 78 of each of the first through sixth unit cells 100, 200, 300, 400, 500, and 600 may have a different shape from first and second dummy patterns 42, 44, 46, and 48 of each of the first through sixth unit cells 100, 200, 300, 400, 500, and 600 of FIG. 3.

The first dummy pattern 76 of the first unit cell 100 may be disposed on an edge of the first unit cell 100. The first dummy pattern 76 of the first unit cell 100 may not be disposed on the third gate pattern 36 to partially cover the first gate pattern 32. The first dummy pattern 76 of the first unit cell 100 may be electrically connected to the first gate pattern 32 through a through hole 68. The through hole 68 may mold the first dummy pattern 76 to expose the first gate pattern 32. The second dummy pattern 78 of the first unit cell 100 may be disposed on an edge of the first unit cell 100 opposite to the first dummy pattern 76. The second dummy pattern 78 of the first unit cell 100 may not be disposed on the second gate pattern 34 to partially cover the fourth gate pattern 38.

The first and second dummy patterns 76 and 78 of the first unit cell 100 may be disposed parallel to each other. The second dummy pattern 78 of the first unit cell 100 may be electrically connected to the fourth gate pattern 38 through a through hole 68. The through hole 68 may mold the second dummy pattern 78 to expose the fourth gate pattern 38. The first and second dummy patterns 76 and 78 of the first unit cell 100 may be exposed through the second end portions of FIG. 3 more than the first and second dummy patterns 42, 44, 46, and 48 of the first unit cell 100 of FIG. 3.

Like in the first unit cell 100, the first and second dummy patterns 76 and 78 may be disposed in each of the second through sixth unit cells 200, 300, 400, 500, and 600. The second dummy pattern 78 of the first unit cell 100 may contact the first dummy pattern 76 of the second unit cell 200 at a first cell boundary line CBL between the first and second unit cells 100 and 200. The through hole 68 extending from the fourth gate pattern 38 of the first unit cell 100 may face the through hole 68 extending from the first gate pattern 32 of the second unit cell 200 along a first direction F1.

The second dummy pattern 78 of the second unit cell 200 may contact the first dummy pattern 76 of the third unit cell 300 at a first cell boundary line CBL between the second and third unit cells 200 and 300. The through hole 68 extending from the fourth gate pattern 38 of the second unit cell 200 may face the through hole 68 extending from the first gate pattern 32 of the third unit cell 300 along the first direction F1. The second dummy pattern 78 of the fourth unit cell 400 may contact the first dummy pattern 76 of the fifth unit cell 500 at a first cell boundary line CBL between the fourth and fifth unit cells 400 and 500.

The through hole 68 extending from the fourth gate pattern 38 of the fourth unit cell 400 may face the through hole 68 extending from the first gate pattern 32 of the fifth unit cell 500 along a second direction F2. The second dummy pattern 78 of the fifth unit cell 500 may contact the first dummy pattern 76 of the sixth unit cell 600 at a first cell boundary line CBL between the fifth and sixth unit cells 500 and 600. The through hole 68 extending from the fourth gate pattern 38 of the fifth unit cell 500 may face the through hole 68 extending from the first gate pattern 32 of the sixth unit cell 600.

The first and second dummy patterns 76 and 78 may increase pattern fidelity to the corresponding photomask thereof more than in the conventional art due to a uniform alignment relationship of the first through sixth unit cells 100, 200, 300, 400, 500, and 600. Since the first or second dummy pattern 76 or 78 is molded by the through hole 68, a distance S3 between the first and fourth gate patterns 32 and 38 in the first through sixth unit cells 100, 200, 300, 400, 500, and 600 may be reduced more than in the conventional art in consideration of a design rule related with a distance S4 between the first and fourth gate patterns 32 and 38.

A distance S1 between the first and second active regions 14 and 18 in the first through sixth unit cells 100, 200, 300, 400, 500, and 600 may be reduced more than in the conventional art. The first through sixth unit cells 100, 200, 300, 400, 500, and 600 may have first and second conductive patterns 94 and 98. The first conductive patterns 94 may be disposed on the first through third unit cells 100, 200, and 300. The first conductive pattern 94 may be electrically connected to the first and second dummy patterns 76 and 78 of the first through third unit cells 100, 200, and 300 through connection holes 85.

The second conductive pattern 98 may be disposed on the fourth through sixth unit cells 400, 500, and 600. The second conductive pattern 98 may be electrically connected to the first and second dummy patterns 76 and 78 of the fourth through sixth unit cells 400, 500, and 600 through connection holes 85. Like in FIG. 3, each of the first and second conductive patterns 94 and 98 of FIGS. 1 and 2 may have the same arrangement structure with respect to the first through fourth gate patterns 32, 34, 36, and 38 of the first through sixth unit cells 100, 200, 300, 400, 500, and 600.

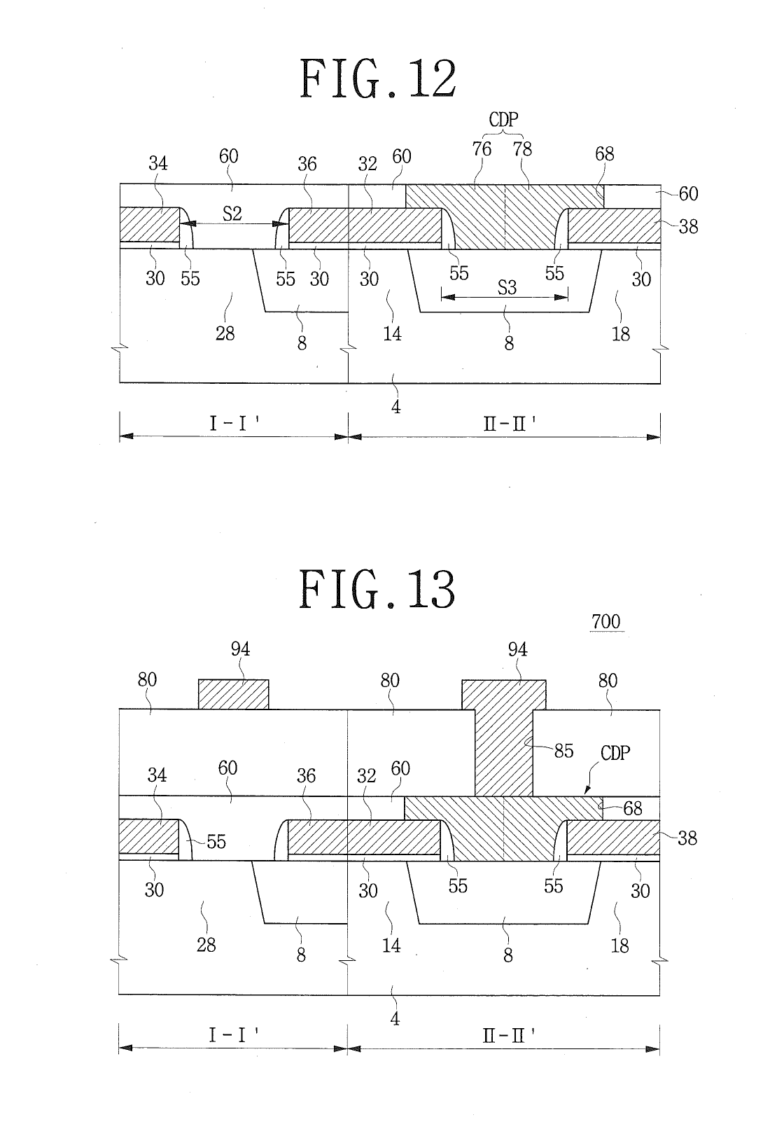

FIGS. 12 and 13 are cross-sectional views taken along lines I-I′ and II-II′ of FIG. 11, illustrating a method of forming a semiconductor cell structure. In FIGS. 12 and 13, the same reference numerals are used to denote the same components as in FIGS. 4 through 6.

Referring to FIG. 12, according to an example embodiment of the inventive concepts, a semiconductor substrate 4 may be prepared. An inactive region 8 and active regions 14, 18, and 28 may be formed on the semiconductor substrate 4. Insulating patterns 30 may be formed on the semiconductor substrate 4. First through fourth gate patterns 32, 34, 36, and 38 may be formed on the insulating patterns 30, respectively. The second and third gate patterns 34 and 36 may face each other at a predetermined or given distance S2 parallel to each other as shown in FIG. 11. The first and fourth gate patterns 32 and 38 may be formed at a predetermined or given distance S3 to diagonally face each other as shown in FIG. 11.

Spacers 55 may be formed on sidewalls of the insulating patterns 30 and the first through fourth gate patterns 32, 34, 36, and 38. An insulating layer 60 may be formed on the semiconductor substrate 4 to cover the first through fourth gate patterns 32, 34, 36, and 38 and the spacers 55. The insulating layer 60 may include an insulating material having a different etch rate from the inactive region 8, the first through fourth gate patterns 32, 34, 36, and 38 and the spacers 55. A through hole 68 may be formed in the insulating layer 60. The through hole 68 may be formed to expose the inactive region 8, the first through fourth gate patterns 32, 34, 36, and 38 and the spacers 55.

First and second dummy patterns 76 and 78 may be formed in the through hole 68. The first and second dummy patterns 76 and 78 may contact each other in the through hole 64 to fill the through hole 68. The first and second dummy patterns 76 and 78 may be aligned with the first through fourth gate patterns 32, 34, 36, and 38 between the first through fourth gate patterns 32, 34, 36, and 38. The first and second dummy patterns 76 and 78 may protrude from top surfaces of the first and fourth gate patterns 32 and 38 in the vicinity of the first and fourth gate patterns 32 and 38.

In addition, the first and second dummy patterns 76 and 78 may extend from the vicinity of the first and fourth gate patterns 32 and 38 toward the top surfaces of the first and gate patterns 32 and 38 and contact the first and fourth gate patterns 32 and 38, respectively. The first and second dummy patterns 76 and 78 may form a substantially planar surface with a top surface of the insulating layer 60. The first and second dummy patterns 76 and 78 may protrude from the top surface of the insulating layer 60 and extend to the vicinity to the through hole 68. The first and second dummy patterns 76 and 78 may include the same material as or a different material from the first through fourth gate patterns 32, 34, 36, and 38. The first and second dummy patterns 76 and 78 may constitute a cell dummy pattern CDP.

Referring to FIG. 13, according to an example embodiment of the inventive concepts, a protection layer 80 may be formed on the insulating layer 60 to cover the first and second dummy patterns 76 and 78. A connection hole 85 may be formed in the protection layer 80. The connection hole 85 may be formed to expose the cell dummy pattern CDP. A first conductive pattern 94 may be formed in the connection hole 85. The first conductive pattern 94 may be formed on the insulating layer 80 to fill the connection hole 85. The semiconductor substrate 4, the first through fourth gate patterns 32, 34, 36, and 38 and the first conductive pattern 94 may constitute the semiconductor cell structure 700.

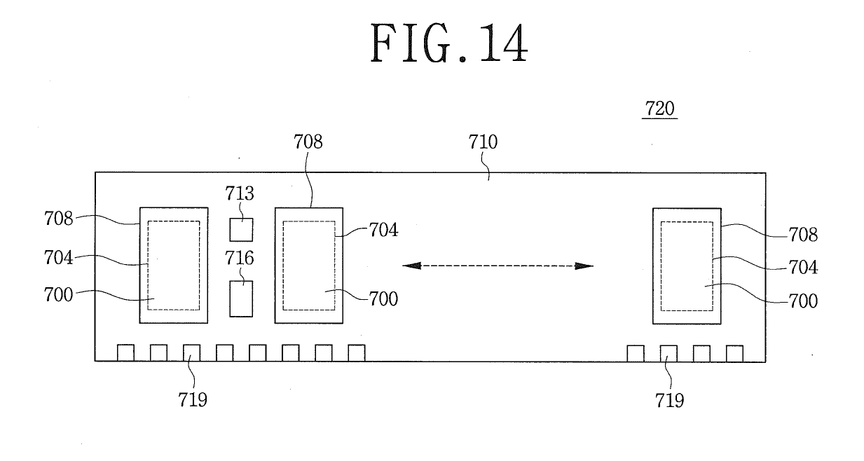

FIG. 14 is a plan view of a semiconductor module according to an example embodiment of the inventive concepts. Referring to FIG. 14, a semiconductor module 720 according to an example embodiment may include a module substrate 710. The module substrate 710 may be a printed circuit board (PCB) or a plate including an electrical circuit. The module substrate 710 may include internal circuits (not shown), electrical pads (not shown), and connectors 719. The internal circuits may be electrically connected to the electrical pads and the connectors 719. Semiconductor package structures 708 and at least one resistor 713 may be disposed on the module substrate 710.

Semiconductor package structures 708, at least one resistor 713, and at least one condenser 716 may be disposed on the module substrate 710. The semiconductor package structures 708 may be electrically connected to the electrical pads along with at least one resistor 713 and/or at least one condenser 716. Each of the semiconductor package structures 708 may include at least one semiconductor device 704. The semiconductor device 704 may include at least one semiconductor cell structure 700 of FIG. 3, FIG. 7, or FIG. 11.

The semiconductor cell structure 700 may include first through sixth unit cells 100, 200, 300, 400, 500, and 600. Like in FIG. 3, FIG. 7, or FIG. 11, the first through three unit cells 100, 200, and 300 may be different in phase from the fourth through sixth unit cells 400, 500, and 600. The first unit cell 100 may include first through fourth active regions 14, 18, 24, and 28 and first through fourth gate patterns 32, 34, 36, and 38. The first through fourth gate patterns 32, 34, 36, and 38 may be disposed on the first through fourth active regions 14, 18, 24, and 28 and have the same arrangement structures as in FIG. 3, FIG. 7, or FIG. 11.

Each of the second through sixth unit cells 200, 300, 400, 500, and 600 may have the same components as the first unit cell 100. The first through sixth unit cells 100, 200, 300, 400, 500, and 600 may include the first and second dummy patterns 42, 44, 46, and 48 of FIG. 3, the first and second dummy patterns 72 and 74 of FIG. 7, or the first and second dummy patterns 76 and 78 of FIG. 11. The first and second dummy patterns 42, 44, 46, and 48 may be disposed between the first and second unit cells 100 and 200, between the second and third unit cells 200 and 300, between the fourth and fifth unit cells 400 and 500, and between the fifth and sixth unit cells 500 and 600.

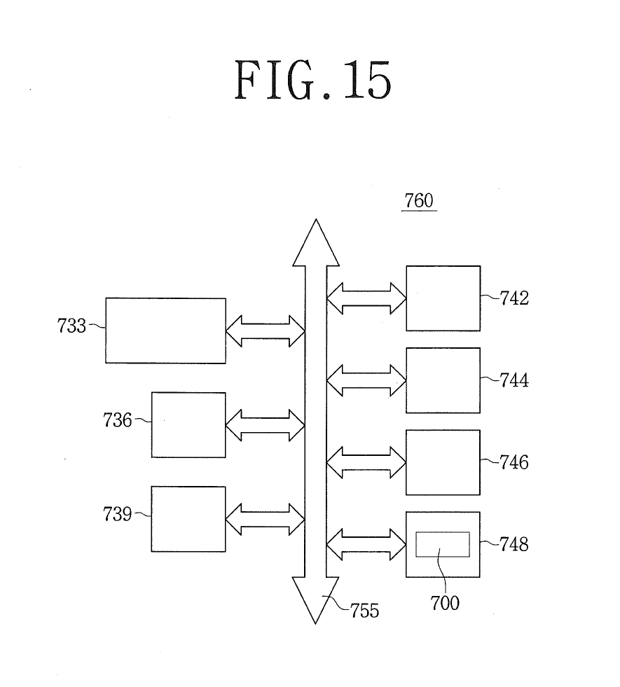

The first and second dummy patterns 42, 44, 46, and 48 may electrically connected the first through sixth unit cells 100, 200, 300, 400, 500, and 600. The first and second dummy patterns 72 and 74 of FIG. 7 or the first and second dummy patterns 76 and 78 of FIG. 11 may perform the same function as the first and second dummy patterns 42, 44, 46, and 48 in the first through sixth unit cells 100, 200, 300, 400, 500, and 600. Thus, the semiconductor module 720 may have improved electrical properties compared with the conventional art. The semiconductor module 720 may be electrically connected to a processor-based system 760 of FIG. 15 through connectors 719 of the module substrate 710.

FIG. 15 is a plan view of a processor-based system according to embodiments. Referring to FIG. 15, a processor-based system 760 according to embodiments may include at least one system board (not shown). The at least one system board may include at least one bus line 755. A first module unit may be disposed on the at least one bus line 755. The first module unit may be electrically connected to the at least one bus line 755.

The first module unit may include a central processing unit (CPU) 733, a floppy disk drive (FDD) 736, and a compact disk (CD) ROM drive 739. Also, a second module unit may be disposed on the at least one bus line 755. The second module unit may be electrically connected to at least one bus line 755. The second module unit may include a first input/output (I/O) device 742, a second I/O device 744, a read-only memory (ROM) 746, and a random access memory (RAM) 748. The RAM 748 may include the semiconductor module 720 of FIG. 14 according to an example embodiment or singly include the semiconductor cell structure 700 of FIG. 3, 7, or 11.

The first or second module unit may include the semiconductor module 720 of FIG. 14 or singly include the semiconductor cell structure 700 of FIG. 3, 7, or 11. Thus, the processor-based system 760 may have improved electrical properties compared with the conventional art. The processor-based system 760 may include a computer system, a process control system, or another system.

As described above, example embodiments of the inventive concepts may provide a semiconductor cell structure having at least the following different structural properties from the conventional art. The semiconductor cell structure can include unit cells that do not protrude from one another along columns and rows. In the semiconductor cell structure, a distance between active regions disposed adjacent to a boundary line between the unit cells can be reduced due to an alignment relationship of the unit cells.

The active regions, gate patterns, and dummy patterns of the unit cells can increase pattern fidelity to the corresponding photomask thereof. The dummy patterns can be disposed at a boundary line between the unit cells. The dummy patterns can be electrically connected to at least portion of the gate patterns in the vicinity of the boundary line between the unit cells.

Conductive patterns disposed on the unit cells can have substantially elongated shapes along columns and rows. The conductive patterns can be electrically connected to the dummy patterns at the boundary line between the unit cells and/or in the vicinity of the boundary line between the unit cells. The conductive patterns can increase pattern fidelity to the corresponding photomask thereof due to an alignment relationship between the unit cells.

The semiconductor cell structure can be disposed in a semiconductor device and a semiconductor module. The semiconductor device and the semiconductor module can adopt the semiconductor cell structure having unit cells which do not protrude from one another in order to improve electrical properties.

The foregoing is illustrative of embodiments and is not to be construed as limiting thereof. Although a few embodiments have been described, those skilled in the art will readily appreciate that many modifications are possible in example embodiments without materially departing from the novel teachings and advantages. Accordingly, all such modifications are intended to be included within the scope of inventive concepts as defined in the claims. In the claims, means-plus-function clauses are intended to cover the structures described herein as performing the recited function, and not only structural equivalents but also equivalent structures. Therefore, it is to be understood that the foregoing is illustrative of various embodiments and is not to be construed as limited to the specific embodiments disclosed, and that modifications to the disclosed embodiments, as well as other example embodiments, are intended to be included within the scope of the appended claims.

What is claimed is:

1. A semiconductor cell structure comprising:
at least one unit cell, each unit cell including,
first through fourth active regions sequentially disposed in the at least one unit cell, the first through fourth active regions parallel to one another,
first and second gate patterns disposed perpendicular to the first, third, and fourth active regions, the second gate pattern being aligned with the first gate pattern, the first gate pattern being disposed on the first active region, and the second gate pattern being disposed on the third and fourth active regions, and
third and fourth gate patterns disposed perpendicular to the first, second, and fourth active regions, the fourth gate pattern being aligned with the third gate pattern, the third and fourth gate patterns parallel to and facing the first and second gate patterns, the third gate pattern being disposed on the first and second active regions, and the fourth gate pattern being disposed on the fourth active region;
first dummy patterns disposed on opposite edges of the at least one unit cell, the first dummy patterns being parallel to one another and configured to electrically connect to the first and fourth gate patterns, respectively; and
a conductive pattern electrically connected to the first dummy patterns to form a straight line interposed between the first through fourth gate patterns.

2. The semiconductor cell structure of claim 1, wherein the first dummy patterns are aligned with the first through fourth gate patterns in a vertical direction along a cross-section of the semiconductor cell structure and contact the first and fourth gate patterns, respectively.

3. The semiconductor cell structure of claim 1, wherein the first dummy patterns are disposed above the first through fourth gate patterns in a vertical direction along a cross-section of the semiconductor cell structure, contact the first and fourth gate patterns, respectively, and partially cover at least one of the first and third gate patterns and at least one of the second and fourth gate patterns.

4. The semiconductor cell structure of claim 1, wherein the first dummy patterns are disposed between the first through fourth gate patterns in a vertical direction along a cross-section of the semiconductor cell structure, protrude from top surfaces of the first and fourth gate patterns and extend at least partially over the top surfaces of the first and fourth gate patterns, respectively.

5. The semiconductor cell structure of claim 1, further comprising a second dummy pattern,
wherein the at least one unit cell includes first, second and third unit cells, the second and third unit cells configured to electrically connect to the first unit cell,
the second unit cell disposed on one of a lower end portion and an upper end, portion of the first unit cell and equal in phase to the first unit cell, the second dummy pattern electrically connected to at least one of the first and fourth gate patterns of the second unit cell and configured to contact the first dummy pattern electrically connected to at least one of the first and fourth gate patterns of the first unit cell at a first cell boundary line between the first and second unit cells, and
the third unit cell disposed on at least one of a left end portion and a right end portion of the first unit cell, the third unit cell including first through fourth active regions, wherein at least one of first, third, and fourth active regions and first, second, and fourth active regions of the third unit cell are configured to electrically connect to at least one of first, third, and fourth active regions and first, second, and fourth active regions of the first unit cell at a second cell boundary line between the first and third unit cells.

6. A semiconductor device comprising:
at least one unit cell in a semiconductor substrate, each unit cell including,
first and second active regions configured to contact first end portions of each unit cell, the first and second active regions sequentially disposed parallel to each other,
third and fourth active regions sequentially disposed parallel to each other between the first and second active regions, the third and fourth active regions configured to extend from the first end portions of each unit cell toward each other,
first and second gate patterns on the first and second active regions, respectively, the first and second gate patterns disposed perpendicular to the first and second active regions and configured to diagonally face each other,
a third gate pattern disposed perpendicular to the second and fourth active regions, the third gate pattern being aligned with the first gate pattern, and
a fourth gate pattern disposed perpendicular to the first and third active regions, the fourth gate pattern being aligned with the second gate pattern;
first and second dummy patterns configured to contact the first and second gate patterns, respectively, extend from the first and second gate patterns, and contact second end portions disposed perpendicular to the first end portions, the first and second dummy patterns disposed parallel to each other; and
a first conductive pattern disposed between the first through fourth gate patterns, the first conductive pattern configured to contact the first and second dummy patterns to form a straight line.

7. The semiconductor device of claim 6, wherein the first and second dummy patterns are aligned with the first through fourth gate patterns and diagonally extend parallel to each other to contact sidewalls of the first and second gate patterns, respectively.

8. The semiconductor device of claim 7, further comprising third and fourth dummy patterns,
wherein the at least one unit cell includes first, second and third unit cells, the second and third unit cells configured to electrically connect to the first unit cell,
the second unit cell disposed on one selected from second end portions of the first unit cell and equal in phase to the first unit cell, at least one of the third and fourth dummy patterns configured to contact at least one of the first and second gate patterns of the second unit cell, wherein the at least one of the third and fourth dummy patterns contacts at least one of the first and second dummy patterns configured to contact at least one of the first and second gate patterns of the first unit cell at a first cell boundary line between the first and second unit cells, and
the third unit cell disposed on one selected from the first end portions of the first unit cell, the third unit cell including first through fourth active regions, wherein at least one of first, second, and third active regions and first, second, and fourth active regions are configured to contact at least one of first, second, and third active regions and first, second, and fourth active regions of the first unit cell at a second cell boundary line between the first and third unit cells.

9. The semiconductor device of claim 8, further comprising:
a second conductive pattern disposed in the third unit cell, the second conductive pattern parallel to the first conductive pattern,
wherein the first conductive pattern extends from the first unit cell to the second unit cell and is disposed between the first through fourth gate patterns of the first and second unit cells to contact the third and fourth dummy patterns, and
the second conductive pattern has the same shape as the first conductive pattern and is disposed between the first through fourth gate patterns of the third unit cell to contact the first and second dummy patterns connected to the third unit cell.

10. The semiconductor device of claim 6,
wherein the first and second dummy patterns are disposed on the first through fourth gate patterns to contact the first and second gate patterns, respectively, and disposed on at least one of the first and fourth gate patterns and at least one of the second and third gate patterns.

11. The semiconductor device of claim 10, further comprising third and fourth dummy patterns,
wherein the at least one unit cell includes first, second and third unit cells, the second and third unit cells configured to electrically connect to the first unit cell,
the second unit cell disposed on one selected from the second end portions of the first unit cell and equal in phase to the first unit cell, at least one of the third and fourth dummy patterns configured to contact at least one of the first and second gate patterns of the second unit cell, the at least one of the third and fourth dummy patterns contacting at least one of the first and second dummy patterns configured to contact at least one of the first and second gate patterns of the first unit cell at a first cell boundary line between the first and second unit cells, and
the third unit cell disposed on one selected from the first end portions of the first unit cell, the third unit cell including first through fourth active regions, wherein at least one of first, second, and third active regions and first, second, and fourth active regions of the third unit cell are configured to contact at least one of first, second, and third active regions and first, second, and fourth active regions of the first unit cell at a second cell boundary line between the first and third unit cells.

12. The semiconductor device of claim 11, further comprising:
a second conductive pattern disposed in the third unit cell, the second conductive pattern parallel to the first conductive pattern,
wherein the first conductive pattern extends from the first unit cell to the second unit cell and is disposed between the first through fourth gate patterns of the first and second unit cells to contact the third and fourth dummy patterns, and
the second conductive pattern has the same shape as the first conductive pattern and is disposed between the first through fourth gate patterns of the third unit cell to contact the first and second dummy patterns connected to the third unit cell.

13. The semiconductor device of claim 6, wherein the first and second dummy patterns are between the first through fourth gate patterns, protrude from top surfaces of the first and second gate patterns, and extend at least partially over the top surfaces of the first and second gate patterns to contact the first and second gate patterns, respectively.

14. The semiconductor device of claim 13, further comprising third and fourth dummy patterns,
wherein the at least one unit cell includes first, second and third unit cells, the second and third unit cells configured to electrically connect to the first unit cell,
the second unit cell disposed on one selected from the second end portions of the first unit cell and equal in phase to the first unit cell, at least one of the third and fourth dummy patterns configured to contact at least one of the first and second gate patterns of the second unit cell, the at least one of the third and fourth dummy patterns contacting at least one of the first and second dummy patterns configured to contact at least one of the first and second gate patterns of the first unit cell at a first cell boundary line between the first and second unit cells, and
the third unit cell disposed on one selected from the first end portions of the first unit cell, the third unit cell including first through fourth active regions, wherein at least one of first, second, and third active regions and first, second, and fourth active regions of the third unit cell are configured to contact at least one of first, second, and third active regions and first, second, and fourth active regions of the first unit cell at a second cell boundary line between the first and third unit cells.

15. The semiconductor device of claim 14, further comprising:
a second conductive pattern disposed in the third unit cell, the second conductive pattern parallel to the first conductive pattern,
wherein the first conductive pattern extends from the first unit cell to the second unit cell and is disposed between the first through fourth gate patterns of the first and second unit cells to contact the third and fourth dummy patterns, and
the second conductive pattern has the same shape as the first conductive pattern and is disposed between the first through fourth gate patterns of the third unit cell to contact the first and second dummy patterns connected to the third unit cell.

16. A semiconductor module comprising:
a module substrate; and
at least one semiconductor package structure electrically connected to the module substrate and including at least one semiconductor device,
wherein the at least one semiconductor device includes a semiconductor cell structure disposed on a semiconductor substrate, and
the semiconductor cell structure includes,
at least one unit cell, each unit cell including,
first through fourth active regions sequentially disposed in the at least one unit cell, the first through fourth active regions parallel to one another,
first and second gate patterns disposed perpendicular to the first, third, and fourth active regions, the second gate pattern being aligned with the first gate pattern, the first gate pattern being disposed on the first active region, and the second gate pattern being disposed on the third and fourth active regions, and
third and fourth gate patterns disposed perpendicular to the first, second, and fourth active regions, the fourth gate pattern being aligned with the third gate pattern, the third and fourth gate patterns parallel to and facing the first and second gate patterns, the third gate pattern being disposed on the first and second active regions, and the fourth gate pattern being disposed on the fourth active region;
first dummy patterns disposed on opposite edges of the at least one unit cell, the first dummy patterns being parallel to one another and configured to electrically connect to the first and fourth gate patterns, respectively; and
a conductive pattern electrically connected to the first dummy patterns to form a straight line interposed between the first through fourth gate patterns.

17. The semiconductor module of claim 16, wherein the first dummy patterns are aligned with the first through fourth gate patterns in a vertical direction along a cross-section of the semiconductor cell structure and contact the first and fourth gate patterns, respectively.

18. The semiconductor module of claim 16, wherein the first dummy patterns are disposed above the first through fourth gate patterns in a vertical direction along a cross-section of the semiconductor cell structure, contact the first and fourth gate patterns, respectively, and partially cover at least one of the first and third gate patterns and at least one of the second and fourth gate patterns.

19. The semiconductor module of claim 16, wherein the first dummy patterns are disposed between the first through fourth gate patterns in a vertical direction along a cross-section of the semiconductor cell structure, protrude from top surfaces of the first and fourth gate patterns and extend at least partially over the top surfaces of the first and fourth gate patterns, respectively.

20. The semiconductor module of claim 16, further comprising a second dummy pattern,
wherein the at least one unit cell includes first, second and third unit cells, the second and third unit cells configured to electrically connect to the first unit cell,
the second unit cell disposed on one of a lower end portion and an upper end portion of the first unit cell and equal in phase to the first unit cell, the second dummy pattern electrically connected to at least one of the first and fourth gate patterns of the second unit cell and configured to contact the first dummy pattern electrically connected to at least one of the first and fourth gate patterns of the first unit cell at a first cell boundary line between the first and second unit cells, and
the third unit cell disposed on at least one of a left end portion and a right end portion of the first unit cell, the third unit cell including first through fourth active regions, wherein at least one of first, third, and fourth active regions and first, second, and fourth active regions of the third unit cell are configured to electrically connect to at least one of first, third, and fourth active regions and first, second, and fourth active regions of the first unit cell at a second cell boundary line between the first and third unit cells.
